(19) United States
(12) Patent Application Publication
(10) Pub. No.: US 2014/0227945 A1
(43) Pub. Date: Aug. 14, 2014

(54) CHEMICAL MECHANICAL PLANARIZATION PLATEN

(71) Applicant: TAIWAN SEMICONDUCTOR MANUFACTURING CO., LTD., Hsin-Chu (TW)

(72) Inventors: Chang-Sheng LIN, Baoshan Township (TW); Hsin-Hsien LU, Hsinchu City (TW)

(73) Assignee: TAIWAN SEMICONDUCTOR MANUFACTURING CO., LTD., Hsin-Chu (TW)

(21) Appl. No.: 13/762,412

(22) Filed: Feb. 8, 2013

(51) Int. Cl. H01L 21/67; B24D 9/10

(52) U.S. Cl. CPC H01L 21/67011; B24D 9/10
USPC 451/41; 451/494; 156/345.12

(57) ABSTRACT

A method and system for planarizing or polishing a semiconductor wafer. The system includes a carrier adaptable to hold a semiconductor wafer, a polishing pad, and a platen having a substantially planar surface in contact with the polishing pad, the planar surface having a distribution of holes. The distributed holes are operatively connected to a vacuum system providing a vacuum pressure to hold the polishing pad against the platen during operation of the system. Relative movement between the carrier and polishing pad acts to planarize a surface of the wafer.

### BACKGROUND

Chemical mechanical planarization or polishing (CMP) is an integral process for smoothing surfaces of semiconductor wafers through both chemical etching and physical abrasion. In an exemplary CMP step, a semiconductor wafer is mounted onto a polishing head which rotates during the CMP process. The polishing head is generally rotated with different axes of rotation to remove material and even out irregular topographies on the wafer. The rotating polishing head presses the semiconductor wafer against a rotating polishing pad affixed to a platen. Slurry containing chemical etchants and colloid particles are applied onto the polishing pad, and irregularities on the wafer surface are removed resulting in a planarization of the semiconductor wafer.

Conventional CMP machines or systems adhere the polishing pad to the platen by pressure sensitive adhesion. Such pad adhesion methods, however, tend to result in an increase in abnormal pad wear and incidents of bubbling and defects on the surface of the polishing. Any of these or other deleterious effects can negatively impact the topography of semiconductor wafers and effectiveness of devices thereon.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features can be arbitrarily increased or reduced for clarity of discussion.

FIG. 1 is a top view of a chemical mechanical planarization tool.

FIG. 2 is a perspective view of the platen, pad and head components of the tool depicted in FIG. 1.

FIGS. 3a-3c are top views of exemplary chemical mechanical planarization platens or tables according to the present disclosure.

FIG. 4 is a block diagram of some embodiments of the present disclosure.

### DETAILED DESCRIPTION

It is understood that the following disclosure provides many different embodiments or examples for implementing different features of various embodiments. Specific examples of components and arrangements are described below to simplify the present disclosure. These are, of course, merely examples and are not intended to be limiting. The present disclosure may repeat reference numerals and/or letters in the various examples. This repetition is for the purpose of simplicity and clarity and does not in itself dictate a relationship between the various embodiments and/or configurations discussed.

Terms used herein are only used to describe the specific embodiments, which are not used to limit the claims appended herewith. For example, unless limited otherwise, the term “one” or “the” of the single form may also represent the plural form. The terms such as “first” and “second” are used for describing various devices, areas and layers, etc., though such terms are only used for distinguishing one device, one area or one layer from another device, another area or another layer. Therefore, the first area can also be referred to as the second area without departing from the spirit of the claimed subject matter, and the others are deduced by analogy. Moreover, space orientation terms such as “under”, “on”, “up”, “down”, etc. are used to describe a relationship between a device or a characteristic and another device or another characteristic in the drawing. It should be noted that the space orientation term can cover different orientations of the device besides the orientation of the device illustrated in the drawing. For example, if the device in the drawing is turned over, the device located “under” or “below” the other devices or characteristics is reoriented to be located “above” the other devices or characteristics. Therefore, the space orientation term “under” may include two orientations of “above” and “below”.

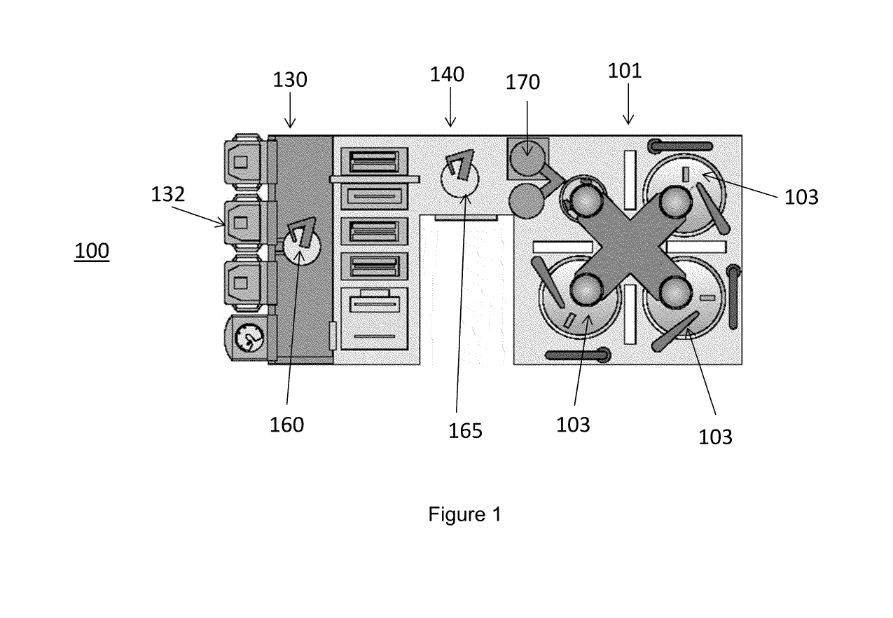

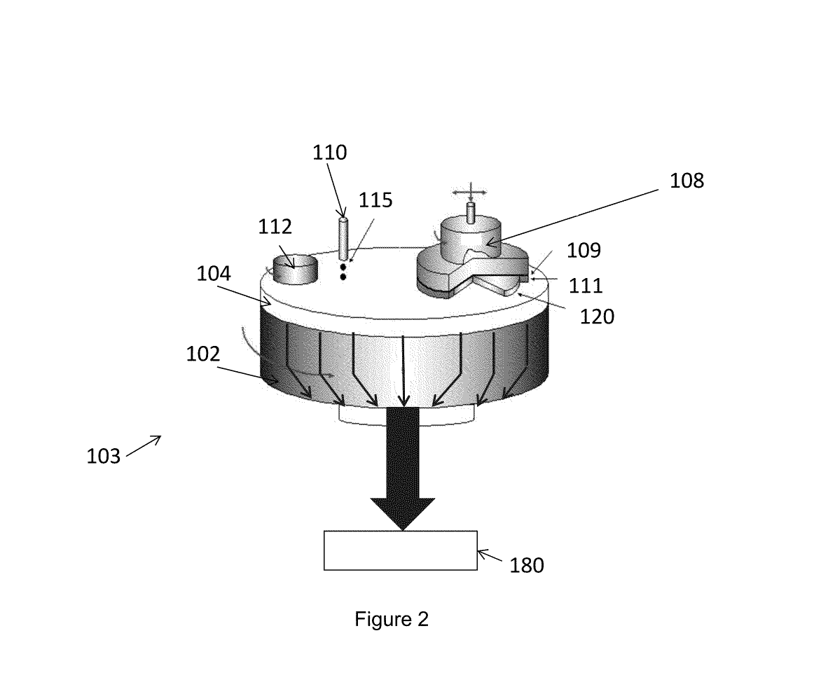

FIG. 1 is a top view of a chemical mechanical planarization tool. FIG. 2 is a perspective view of the platen, pad and head components of the tool depicted in FIG. 1. With reference to FIGS. 1 and 2, one or more semiconductor wafers can be subjected to a chemical mechanical planarization or polishing (CMP) process using an exemplary CMP system 100. An exemplary CMP system 100 generally includes a factory interface 130, a cleaning module 140 and a polishing or planarization module 101. in some embodiments, a dry robot 160 is provided to transfer substrates or wafers between the factory interface 130 and the cleaning module 140, and a wet robot 165 is provided to transfer substrates or wafers between the cleaning module 140 and the planarization module 101. While not shown, in other embodiments the wet robot 165 can be configured to transfer substrates or wafers between the factory interface 130, cleaning module 140 and/or the polishing module 101.

The factory interface 130 generally includes the dry robot 160 which is configured to transfer substrates or wafers between one or more cassettes 132 and the cleaning module 140. in the embodiment depicted in FIG. 1, four storage cassettes 132 are shown, however, embodiments according to the present disclosure should not be so limited as any number of cassettes are envisioned. The dry robot 160 generally has sufficient range of motion to facilitate transfer between the storage cassettes 132 and the cleaning module 140. Optionally, the range of motion of the dry robot 160 can be increased by adding additional linkages to the robot or placing the robot on a rail mechanism. As depicted, the dry robot 160 is also configured to receive substrates or wafers from the cleaning module 140 and return cleaned, polished substrates or wafers to the substrate storage cassettes 132. The wet robot 165 generally has sufficient range of motion to transfer substrates or wafers between the cleaning module 140 and one or more load cups 170 disposed on the planarization module 101. Range of motion of the wet robot 165 can also be increased by adding additional linkages to the robot or placing the robot on a rail mechanism.

The planarization module 101 includes a plurality of planarization stations 103 each having one or more rotating tables or platens 102 covered by a polishing pad 104. In some embodiments of the present disclosure, the polishing pad 104 is adhered to the platen 102 through a vacuum system 180 external or internal to the CMP system 100. The platen 102 can be provided with a series of distributed holes (not shown) operatively connected to the vacuum system 180 allowing the polishing pad 104 to be subjected to an appropriate vacuum. The level of vacuum can be monitored and/or controlled using conventional pressure monitors and fixtures internal or external to the planarization module 101 to uniformly distribute the vacuum along the underside of the polishing pad 104 and adhere the pad 104 to the platen 102 thereby resulting in a controlled flatness of the respective polishing surface. In various embodiments of the present disclosure, the vacuum can be maintained at pressures of approximately or greater than 1000 hPa. Of course, the vacuum can be varied and can be less than 1000 hPa to control or adjust the flatness of the pad 104 surface and such an exemplary pressure should not limit the scope of the claims appended herewith. It is envisioned that embodiments of the present disclosure can employ any suitable vacuum system utilized in the industry to adhere the polishing pad 104 to the platen 102.

Exemplary polishing pads 104 can be comprised of cast or sliced polyurethane, polyurethane impregnated polyester felt, or another suitable material. A wafer 120 being polished is generally mounted upside down in a carrier, head or spindle 108. The carrier, head or spindle 108 is adaptable to accept wafers from and return wafers to the load cup 170. Wafers 120 can be held by vacuum to the carrier, head or spindle 108 or held thereto by a backing film 109. In some embodiments the wafer 120 is encompassed by a retainer ring 111. A slurry 115 can be introduced on the polishing pad 104 via a slurry introduction mechanism 110. Exemplary slurries 115 comprise an abrasive(s) suspended in an alkaline, neutral or acidic solution, depending upon the process requirement, i.e., chemical etchants and colloid particles.

Pad conditioners 112 can also be employed to prepare and condition the surface of the pad 104 during, before and/or after CMP processes. The polishing spindle 108 is generally rotated with different axes of rotation to remove material and even out irregular topographies on the semiconductor wafer 120. The rotating polishing spindle 108 presses the semiconductor wafer 120 against the rotating polishing pad 104 and slurry 115 containing chemical etchants and colloid particles are introduced using the slurry introduction mechanism 110 onto the polishing pad 104. Through this active rotation of a wafer 120 on a polishing platen 102 and pad 104 under pressure in a presence of a polishing medium, irregularities on the wafer surface are removed during one or more CMP processes thereby resulting in a planarization of the semiconductor wafer 120.

An exemplary CMP system 100 can achieve global planarization of respective wafer surfaces and can be utilized to planarize all types of surfaces including, but not limited to, multi-material surfaces. During an exemplary CMP process, chemical reaction facilitates the formation of surface layers on the wafer being polished which is reactively softer than the original surface. Subsequent mechanical removal of these softer surface layers occurs through abrasion with the polishing pad 104. It should be understood that the one or more CMP processes can encompass any combinations of CMP processes. For example, only one CMP process is used in some embodiments. In other embodiments, the one or more CMP processes include a first and a second CMP process, and different types of slurry are used in the performing the first and second CMP processes. The wafer can include any suitable semiconductor material including, but not limited to, silicon, germanium, a compound semiconductor, and a semiconductor-on-insulator (SOI) substrate. A compound semiconductor can be an III-V semiconductor compound such as gallium arsenide (GaAs). An SOI substrate can comprise a semiconductor on an insulator such as glass. Other portions (not shown) of a semiconductor device can be formed on the wafer including, but not limited to, a buffer layer, an isolator layer or isolation structure such as a shallow trench isolation (STI) structure, a channel layer, a source region and a drain region.

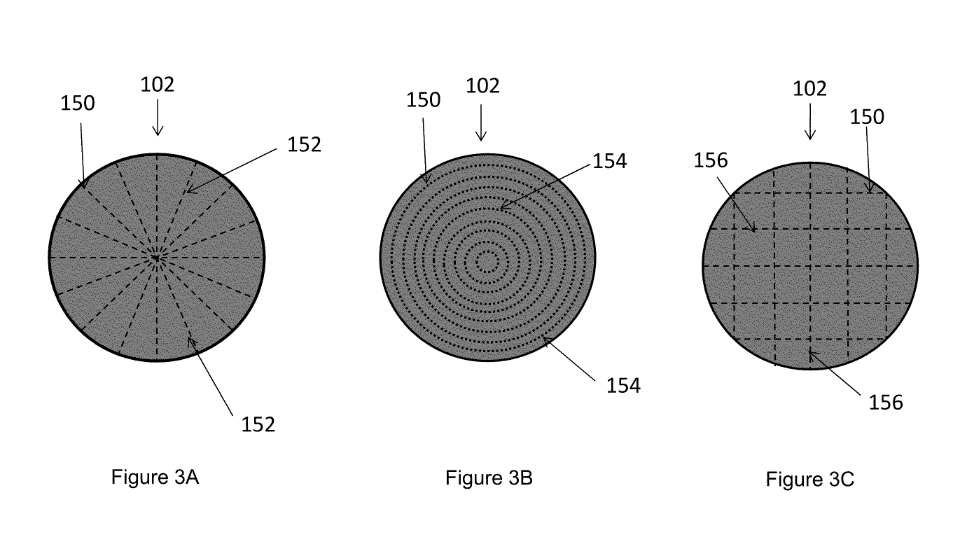

FIGS. 3a-3c are top views of exemplary chemical mechanical planarization platens or tables according to the present disclosure. With reference to FIGS. 3a-3c, an exemplary CMP table or platen 102 includes a series of distributed holes 150 allowing an adjacent polishing pad to be subjected to an appropriate vacuum. As depicted in FIG. 3a, the holes 150 can be radially distributed on the surface of the platen 102, e.g., distributed along a plurality or series of radial lines 152 emanating from a central node of the platen 102. In some embodiments, the holes 150 can be concentrically distributed on the surface of the platen 102, e.g., distributed along a pattern of plural concentric circles 154 as illustrated in FIG. 3b, In other embodiments, the holes 150 can be distributed along a pattern of grid lines 156 on the surface of the platen 102 as illustrated in FIG. 3c. Of course, the embodiments depicted in FIGS. 3a-3c are exemplary only and should not limit the scope of the claims appended herewith as any hole shape, hole size, hole pitch, hole number and distribution pattern is envisioned by the present disclosure. For example, embodiments of the present disclosure can include any symmetrical or asymmetrical hole pattern or combination thereof, can include various hole shapes (e.g., circle, triangle, square, or other suitable geometry), can include various or combinations of hole sizes (e.g., 0.1 mm to approximately 2.5 mm or more), can include various hole pitches (i.e., the distance between similar edges or points of adjacent holes) (e.g., from 2-5 times the size of the hole), and can include any number of holes in any pattern or combination of patterns. Thus, through such exemplary platens 102 and respective distribution of holes, a polishing pad 104 can be subjected to an appropriate vacuum to provide a method and system of adhering and/or removing the pad 104 from the surface of the platen 102 as well as a method and system of controlling the flatness or planarity of the polishing surface of the pad 104.

Some embodiments of the present disclosure provide an exemplary CMP system having a carrier adaptable to hold a semiconductor wafer. In some embodiments, the wafer is held upside down in the carrier with the wafer surface to be planarized facing a respective polishing pad. The wafer can be held by vacuum, by a backing film or other suitable means to the carrier. The system also includes a polishing pad and a platen having a substantially planar surface in contact with the polishing pad. The polishing pad can be constructed of any suitable material such as, but not limited to, cast polyurethane, sliced polyurethane, and polyurethane impregnated polyester felt. This planar surface includes a distribution of holes, where the distributed holes are operatively connected to a vacuum system providing a vacuum pressure to hold the polishing pad against the platen during operation of the system. In some embodiments, the vacuum system is external or internal to the CMP system. The distributed holes can be provided along the surface of the platen in a pattern including radial lines, concentric circles, grid lines, or other suitable patterns. These patterns can be symmetrical or asymmetrical and the distributed holes can each have suitable geometries such as a triangle, square, circle, etc. Further, exemplary holes can have varying widths from approximately 0.1 mm to approximately 2.5 mm. Relative movement between the carrier and polishing pad then acts to planarize a surface of the wafer.

Other embodiments of the present disclosure provide a semiconductor polishing system including a wafer carrier, a platen having a substantially planar surface in contact with a proximate surface of a polishing pad, the planar surface having a distribution of holes, and a vacuum system in connection with each of the distributed holes. A distal surface of the polishing pad is kept substantially flat as a function of a uniform distribution of vacuum pressure applied to the proximate surface of the pad by the distributed holes. The distributed holes can be provided along the surface of the platen in a pattern including radial lines, concentric circles, grid lines, or other suitable patterns. These patterns can be symmetrical or asymmetrical and the distributed holes can each have suitable geometries such as a triangle, square, circle, etc. Further, exemplary holes can have varying widths from approximately 0.1 mm to approximately 2.5 mm. Relative movement between the wafer carrier and polishing pad acts to polish a surface of a wafer carried by the wafer carrier.

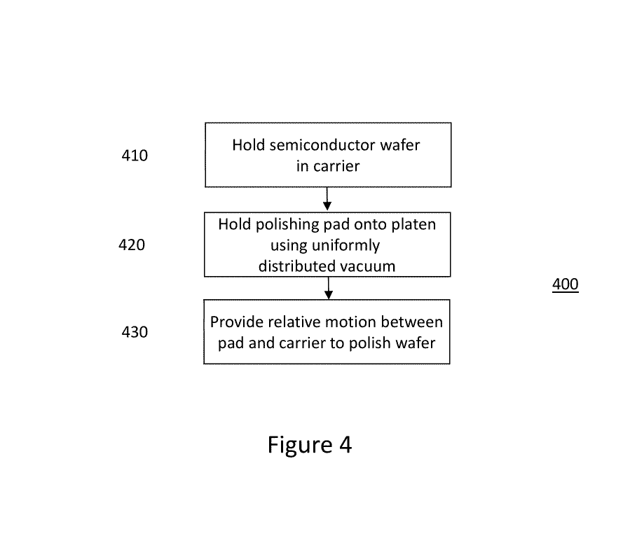

FIG. 4 is a block diagram of some embodiments of the present disclosure. With reference to FIG. 4, a method 400 of polishing a semiconductor wafer is provided. The method 400 includes holding a semiconductor wafer in a carrier at step 410. In other embodiments, step 410 includes holding the wafer in the carrier by vacuum or by a backing film. At step 420, a polishing pad can be held onto a platen using a uniformly distributed vacuum pressure applied to a proximate surface of the polishing pad from the platen. In various embodiments, step 420 includes providing a distribution of holes on a surface of the platen in contact with the proximate surface of the polishing pad, the distribution of holes adaptable to apply the uniformly distributed vacuum pressure to the proximate surface of the polishing pad. In additional embodiments of the present disclosure, the distributed holes are provided along the platen surface in various patterns such as, but not limited to, radial lines, concentric circles, grid lines, or other suitable patterns and combinations thereof. At step 430, relative motion can be provided between the carrier and polishing pad to polish a surface of the wafer. In some embodiments, step 430 includes rotating the carrier with different axes of rotation and rotating the platen.

One of the broader forms of the present disclosure involves a chemical mechanical planarization (CMP) system. The CMP system comprises a carrier adaptable to hold a semiconductor wafer; a polishing pad; and a platen having a substantially planar surface in contact with the polishing pad, the planar surface having a distribution of holes. The distributed holes are operatively connected to a vacuum system providing a vacuum pressure to hold the polishing pad against the platen during operation of the system, and relative movement between the carrier and polishing pad acts to planarize a surface of the wafer.

Another of the broader forms of the present disclosure involves a semiconductor polishing system. The semiconductor polishing system comprises a wafer carrier, a platen having a substantially planar surface in contact with a proximate surface of a polishing pad, the planar surface having a distribution of holes, and a vacuum system in connection with each of the distributed holes. A distal surface of the polishing pad is kept substantially flat as a function of a uniform distribution of vacuum pressure applied to the proximate surface of the pad by the distributed holes.

Still another of the broader forms of the present disclosure involves a method of polishing a semiconductor wafer. The method comprises the steps of holding a semiconductor wafer in a carrier; holding a polishing pad onto a platen using a uniformly distributed vacuum pressure applied to a proximate surface of the polishing pad from the platen; and providing relative motion between the carrier and polishing pad to polish a surface of the wafer.

It can be emphasized that the above-described embodiments, particularly any “preferred” embodiments, are merely possible examples of implementations, merely set forth for a clear understanding of the principles of the disclosure. Many variations and modifications can be made to the above-described embodiments of the disclosure without departing substantially from the spirit and principles of the disclosure. All such modifications and variations are intended to be included herein within the scope of this disclosure and the present disclosure and protected by the following claims.

Further, the foregoing has outlined features of several embodiments so that those skilled in the art can better understand the detailed description that follows. Those skilled in the art should appreciate that they can readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they can make various changes, substitutions and alterations herein without departing from the spirit and scope of the present disclosure.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing can be advantageous.

As shown by the various configurations and embodiments illustrated in FIGS. 1-4, various improved CMP platens have been described

While preferred embodiments of the present subject matter have been described, it is to be understood that the embodiments described are illustrative only and that the scope of the invention is to be defined solely by the appended claims when accorded a full range of equivalence, many variations and modifications naturally occurring to those of skill in the art from a perusal hereof.

We claim:

1. A chemical mechanical planarization (CMP) system comprising:
a carrier adaptable to hold a semiconductor wafer;
a polishing pad; and
a platen having a substantially planar surface in contact with the polishing pad, the planar surface having a distribution of holes,
wherein the distributed holes are operatively connected to a vacuum system providing a vacuum pressure to hold the polishing pad against the platen during operation of the system, and
wherein relative movement between the carrier and polishing pad acts to planarize a surface of the wafer.

2. The CMP system of claim 1 wherein the polishing pad is comprised of a material selected from the group consisting of cast polyurethane, sliced polyurethane, or polyurethane impregnated polyester felt.

3. The CMP system of claim 1 wherein the wafer is held upside down in the carrier with the wafer surface to be planarized facing the polishing pad.

4. The CMP system of claim 3 wherein the wafer is held by vacuum or by a backing film to the carrier.

5. The CMP system of claim 1 wherein the vacuum system is external to the CMP system.

6. The CMP system of claim 1 wherein the distributed holes are provided along the surface of the platen in a pattern selected from the group consisting of radial lines, concentric circles, grid lines, or combinations thereof.

7. The CMP system of claim 1 wherein each of the distributed holes has geometries selected from the group consisting of a triangle, square, circle, or combinations thereof.

8. The CMP system of claim 1 wherein each of the distributed holes has a width of approximately 0.1 mm to approximately 2.5 mm.

9. The CMP system of claim 1 wherein the distribution of holes is symmetrical.

10. A semiconductor polishing system comprising:
a wafer carrier;
a platen having a substantially planar surface in contact with a proximate surface of a polishing pad, the planar surface having a distribution of holes; and
a vacuum system in connection with each of the distributed holes;
wherein a distal surface of the polishing pad is kept substantially flat as a function of a uniform distribution of vacuum pressure applied to the proximate surface of the pad by the distributed holes.

11. The semiconductor polishing system of claim 10 wherein relative movement between the wafer carrier and polishing pad acts to polish a surface of a wafer carried by the wafer carrier.

12. The semiconductor polishing system of claim 10 wherein the distributed holes are provided along the surface of the platen in a pattern selected from the group consisting of radial lines, concentric circles, grid lines, or combinations thereof.

13. The semiconductor polishing system of claim 10 wherein each of the distributed holes has geometries selected from the group consisting of a triangle, square, circle, or combinations thereof.

14. The semiconductor polishing system of claim 10 wherein each of the distributed holes has a width of approximately 0.1 mm to approximately 2.5 mm.

15. The semiconductor polishing system of claim 10 wherein the distribution of holes is symmetrical.

16. A method of polishing a semiconductor wafer comprising the steps of:
holding a semiconductor wafer in a carrier;
holding a polishing pad onto a platen using a uniformly distributed vacuum pressure applied to a proximate surface of the polishing pad from the platen; and
providing relative motion between the carrier and polishing pad to polish a surface of the wafer.

17. The method of claim 16 wherein the step of providing relative motion further comprises rotating the carrier with different axes of rotation and rotating the platen.

18. The method of claim 16 wherein the step of holding a polishing pad further comprises providing a distribution of holes on a surface of the platen in contact with the proximate surface of the polishing pad, the distribution of holes adaptable to apply the uniformly distributed vacuum pressure to the proximate surface of the polishing pad.

19. The method of claim 18 wherein the distributed holes are provided along the platen surface in a pattern selected from the group consisting of radial lines, concentric circles, grid lines, or combinations thereof.

20. The method of claim 16 wherein the step of holding a semiconductor wafer further comprises holding the wafer in the carrier by vacuum or by a backing film.
